(19) United States
(12) Patent Application Publication
(10) Pub. No.: US 2025/0256955 A1
(43) Pub. Date: Aug. 14, 2025

(54) METHOD FOR ASSEMBLING TWO SUBSTRATES BY MOLECULAR ADHESION AND STRUCTURE OBTAINED BY SUCH A METHOD

(71) Applicant: Soitec, BERNIN (FR)

(72) Inventors: Marcel Broekaart, Bernin (FR); Morgane Logiou, BERNIN (FR)

(21) Appl. No.: 18/857,035

(22) PCT Filed: Apr. 12, 2023
(86) PCT No.: PCT/EP2023/059486

§ 371 Date: Oct. 15, 2024

(30) Foreign Application Priority Data
Apr. 19, 2022 (FR) 2203592

(51) Int. Cl. B81C 1/00

(52) U.S. Cl. CPC B81C 1/00357; B81C 2201/019

(57) ABSTRACT

A method for assembly by molecular adhesion of two substrates each having a main face, at least one of the two substrates bearing a dielectric surface layer on its main face, comprises (a) contacting the main faces of the two substrates, then (b) initiating and propagating a bonding wave between the main faces of the two substrates to assemble them with one another. Prior to the contacting of the main faces, sulfur is introduced into the dielectric surface layer at a dose of more than 3.0 E13 at/cm^2 into this layer. A joined structure is obtained via the method.

### CROSS-REFERENCE TO RELATED APPLICATIONS

This application is a national phase entry under 35 U.S.C. § 371 of International Patent Application PCT/EP2023/059486, filed Apr. 12, 2023, designating the United States of America and published as International Patent Publication WO 2023/202917 A1 on Oct. 26, 2023, which claims the benefit under Article 8 of the Patent Cooperation Treaty of French Patent Application Serial No. FR2203592, filed Apr. 19, 2022.

### TECHNICAL FIELD

The present disclosure finds use especially in the fields of microelectronics, microsystems, photonics, etc.

### BACKGROUND

Molecular adhesion is a process for joining two bodies, during which the perfectly clean, flat and smooth main faces or surfaces of these two bodies are brought into intimate contact with each other so as to promote the formation of molecular bonds, for example bonds of the van der Waals or covalent type. The joining of the two bodies is thus achieved without the use of an adhesive. These bonds may be strengthened by the application of a heat-treatment to the join.

This process is used, in particular, for the production of substrates that find use in the fields of microelectronics, microsystems, photonics, etc. In these fields the substrates generally take the form of circular wafers of materials that may be monocrystalline, polycrystalline or amorphous, conductors, semiconductors or insulators.

In these fields and to facilitate the joining of the substrates, it is customary to form a dielectric layer, typically of silicon oxide, on one and/or the other of these two substrates, by deposition, optionally followed by a step of polishing, or by simple oxidation when the substrate is formed from or contains silicon. It is also customary to prepare the main faces so as to render them clean (especially with respect to particles and contaminants) and smooth (so as to provide a surface roughness typically of below 0.5 nm as a root mean square value over a 5 microns by 5 microns field of view). At least one of these faces is sometimes rendered reactive by application of a plasma, typically of oxygen or nitrogen. The aim of this surface preparation is to obtain, immediately after the step of joining and before any thermal annealing, a maximum bonding energy.

After they have been prepared, the two substrates are arranged one on top of the other, on their main faces. The application of pressure to one or the other of the two substrates causes intimate point contact between the main faces and the propagation of this intimate contact across the entirety of the main faces in the form of a wave termed a “bonding wave.”

The patent, technical and scientific literature contains plenty of documents outlining the principles and use of such an adhesion process. Reference may be made, in particular, to the publication by Rieutord et al. “Dynamics of a bonding front,” Physical Review Letters, vol. 94, pp. 236101, 2005.

A recurrent problem encountered in the deployment of a molecular adhesion process is the occurrence of peripheral defects (often referred to as “pimples”) at the bonding interface, at the points where the bonding wave meets the edge of the substrates. When the wave is initiated at an edge of a substrate, these peripheral defects are arranged in a peripheral area generally arranged at the edge diametrically opposite the point of initiation of the wave. When the wave is initiated in a central zone of one of the substrates, these peripheral defects may be arranged at the entire outline. These defects result in the trapping of gas and/or water at the bonding interface between the two substrates. Where such defects occur, the two substrates are not in contact and the local adhesion energy is very low or even nonexistent. These defects, although present, are not necessarily visible immediately after the propagation of the bonding wave, but may emerge during thermal annealing of the structure formed by the two substrates joining together.

The velocity of the bonding wave has been identified as being a factor influencing the number of defects, and reduction of this velocity generally results in a reduction in the number of defects or even their elimination altogether. To this end, various techniques to control this velocity have been proposed, especially via treatment of the surface of one and/or the other of the substrates, in particular, by heating (WO2007060145). Another approach that has been proposed with a view to reducing the velocity of the bonding wave is to direct, at the moment of bonding, a jet of gas, optionally hot, in the direction of the point of initiation of the bonding wave. However, such treatments, if able to effectively bring about a reduction in bonding velocity are also liable to reduce the adhesion energy, which can be detrimental for some applications. Document WO2013160841 discloses maintaining the substrates, during propagation of the wave, in an atmosphere of a gas having a negative Joule-Thomson coefficient at the temperature and pressure of the atmosphere, for example an atmosphere of helium, neon or hydrogen.

Irrespective of the prior art solution that is chosen and however effective it may be, the solution constitutes a significant constraint.

### BRIEF SUMMARY

An aim of the present disclosure is to provide a process for joining by molecular adhesion that differs from the prior art and that makes it possible to prevent or at least limit the occurrence of “pimple”-type defects. More specifically, an aim of the present disclosure is to provide a process for joining by molecular adhesion that is able to provide high bonding energy alongside a number of “pimple”-type defects much lower than in the processes of the prior art and without the process being subject to the constraints of the prior art.

In order to achieve this aim, the subject matter of the present disclosure provides a process for the joining by molecular adhesion of two substrates each having a main face, at least one of the two substrates being provided with a dielectric surface layer on the side of its main face. The process comprises the following steps:
a) the contacting of the main faces of the two substrates, then;
b) the initiating and propagating of a bonding wave between the main faces of the two substrates so as to join the two faces together.

The process is noteworthy in that it includes, before the contacting step, a step of preparing of the dielectric surface layer with the aim of introducing into this layer a dose of sulfur of greater than 3.0 E13 at/cm^2.

The introduction of sulfur in the surface layer and at such a dose surprisingly makes it possible to prevent or at least limit the occurrence of pimple-type defects, even when the two substrates are joined with a high bonding energy.

According to other advantageous and non-limiting features of the present disclosure, taken alone or in any technically feasible combination:
the dose of sulfur introduced is 3.5 E13 at/cm^2;
the step of preparing of the dielectric surface layer also aims to introduce into this layer a dose of fluorine of greater than 4.0 E14 at/cm^2;
the preparation step includes the activation of the dielectric surface layer by a plasma of a gas comprising sulfur;
the preparation step includes the activation of the dielectric surface layer by a plasma comprising sulfur hexafluoride;
the plasma also comprises oxygen or nitrogen;
the activation of the surface layer is carried out for an activation time of between 15 seconds and 2 minutes;
the surface layer is exposed to a plasma of oxygen or nitrogen throughout the duration of the activation, and a controlled amount of sulfur hexafluoride is mixed with the oxygen or nitrogen for a specified period of the activation time;
the specified period is respectively preceded and followed by periods during which the dielectric surface layer is exposed to a plasma formed from an activating gas of oxygen or nitrogen;
the preparation step includes preparing a chamber of a plasma activation apparatus with a plasma of a gas comprising sulfur and then, once the chamber has been prepared, treating the dielectric surface layer in the chamber with a plasma comprising oxygen or nitrogen;
the preparation step includes preparing a chamber of a plasma activation apparatus with a plasma comprising sulfur hexafluoride and then, once the chamber has been prepared, treating the dielectric surface layer in the chamber with a plasma comprising oxygen or nitrogen;
the joining process includes the heat-treatment of the two substrates joined together;
the two substrates are provided with a dielectric surface layer of silicon oxide or silicon nitride on the side of their main face, and the preparation step is carried out on each of the dielectric surface layers;
the dielectric surface layer is composed of silicon oxide;
the silicon oxide in the dielectric surface layer incorporates nitrogen, preferably in a nitrogen/oxygen ratio of less than 0.5;
the dielectric surface layer is composed of silicon nitride;
the joining process includes a step of cleaning of at least one of the main faces of the two substrates, between the preparation step and the contacting step.

According to another aspect, the present disclosure provides a structure comprising a support substrate, a dielectric buried layer arranged on and in contact with the support substrate, and a layer termed a “working layer” on and in contact with the buried layer.

According to the present disclosure, the dielectric buried layer contains a dose of sulfur of greater than 3.0 E13 at/cm^2.

According to other advantageous and non-limiting features of the present disclosure, taken alone or in any technically feasible combination:
the dose of sulfur is greater than 3.5 E13 at/cm^2;
the dielectric buried layer contains a dose of fluorine of greater than 4.0 E14 at/cm^2.
the dielectric buried layer is composed of silicon oxide;
the silicon oxide in the dielectric buried layer incorporates nitrogen, preferably in a nitrogen/oxygen ratio of less than 0.5;
the dielectric buried layer is composed of silicon nitride;

### BRIEF DESCRIPTION OF THE DRAWINGS

Other features and advantages of the present disclosure will become apparent from the detailed description of the present disclosure below, this description being given with reference to the appended figures, in which:

FIGS. 1A and 1B show two examples of a joining process according to the present disclosure;

FIG. 2 shows a structure that can be obtained by way of a process according to the present disclosure.

### DETAILED DESCRIPTION

The present disclosure relates to a process for joining two substrates by molecular adhesion.

The two substrates may be of any kind, insulating (such as quartz, glass or a piezoelectric material), conductive (a metal) or a semiconductor (such as silicon, gallium nitride, silicon carbide), in any of their available forms: monocrystalline, polycrystalline or amorphous. The two substrates may each combine materials of different kinds. For example, one of the two substrates may be formed from a piezoelectric layer transferred directly or by way of an intermediate layer, for example, an adhesive, on a silicon support. The two substrates may be of the same kind or of different kinds. They may especially have a coefficient of thermal expansion different from one another, which limits the temperature to which the joined structure may be exposed, especially so as to increase the bonding energy between the two substrates. The substrates may take the form of circular wafers, having a standardized diameter of 150, 200 or 300 mm, as is generally the case in the field of microelectronics, but the present disclosure is in no way limited to the joining of two wafers that are circular or have a standardized size.

Irrespective of the nature and shape of the two substrates, the substrates are intended to be joined together through their “main” faces.

To facilitate this joining, at least one of the two substrates is provided on the side of its main face with a dielectric layer, for example, a layer of silicon oxide or of silicon nitride. This dielectric surface layer therefore constitutes the joining surface. It may be of any thickness, this being typically between a few nm and a few microns, for example, between 1 nm and 5 microns. In some cases, the two substrates may be provided with one such dielectric surface layer.

The term “silicon oxide layer” denotes a thin layer consisting mainly of silicon oxide. Other chemical elements may also be incorporated therein, in trace amounts or higher concentrations, as will be elucidated later in this description. This layer may especially incorporate nitrogen (so as to form a layer of SiON), for example, in a nitrogen/oxygen ratio of less than 0.5. The proportion of nitrogen in the layer may be characterized through measurement of its refractive index, which ranges (at a wavelength of 620 nm) from 1.44 for SiO₂ to 2.35 for Si₃N₄.The dielectric surface layer may therefore be formed from SiO₁₋ₓNₓ, where the proportion x of nitrogen in the layer may be between 0 and 1.

The dielectric surface layer(s) may be formed by any suitable technique. When the substrate comprises silicon, a dielectric surface layer of silicon oxide may be formed by dry or wet oxidation. More generally, this dielectric surface layer may be formed by deposition. By way of example, this may involve an LPCVD (low-pressure chemical vapor deposition) or PECVD (plasma-enhanced chemical vapor deposition) deposition technique. It may also involve a technique of deposition by centrifugation known as “spin on glass.” The deposited dielectric layer may be polished to reduce its roughness and render it compatible with the joining process, typically to below a value of 0.7 nm as a root mean square value over a 5 microns by 5 microns field of view.

More generally, the exposed surfaces of the main faces are prepared during a preliminary step of preparing the two substrates so as to render them clean (especially with respect to particles and contaminants) and smooth (to provide a surface roughness below the abovementioned value). To this end, a process according to the present disclosure may include prior steps of cleaning and/or polishing of the substrates, which are well known per se, so as to condition these two substrates for the subsequent joining steps. The cleaning step may include especially the brushing of the main faces while pouring onto these surfaces a liquid such as deionized water.

As mentioned in the introduction of the present disclosure, these joining steps comprise:
a) the contacting of the two substrates by their main faces, then;
b) the initiating and propagating of a bonding wave between the two substrates so as to join the two faces together.

By way of illustration only, these joining steps may be carried out in an automated joining apparatus. In this case, a first substrate is manipulated by the arm of an equipment-handling system so as to arrange it on a flat support such that its main face is exposed. The second substrate is then manipulated by the arm of the handling system so as to bring it into contact, on the side of its main face, with the first substrate. An apparatus actuator is moved to apply a moderate pressure of a few newtons on the exposed surface of the second substrate so as to bring about intimate contact between the first substrate and second substrate and the initiation and propagation of the bonding wave. This pressure may be applied anywhere, especially on a peripheral portion or on a central portion of the exposed face of the second substrate.

In all cases and irrespective of the manner with which this wave has been initiated, the bonding wave is propagated from the place of initiation toward the peripheral portion of the joined structure so as to bring the two substrates into intimate contact over the entire extent of their main faces. The propagation of the wave is not instantaneous and this propagation may continue for several seconds, depending, of course, on the size of the substrates.

It is also customary to provide a step of preparing of the dielectric surface layer (or dielectric surface layers when both substrates are provided with such a layer) by plasma activation, typically with a plasma of oxygen or nitrogen. This preparation step may involve placing the substrate in a chamber of a plasma activation apparatus, for example, on a flat support arranged in the chamber, so as to expose the surface layer to a plasma prepared by a source. A flow of oxygen or nitrogen is introduced into the plasma source of the apparatus at a controlled flow rate and a plasma of this gas is generated, for example, by way of variable magnetic or electric fields. The plasma species are directed at the dielectric surface layer so as to activate the face of the substrate. These operations may be performed at or below atmospheric pressure. This activation generally makes it possible to increase the bonding energy between the two substrates immediately after joining or after application of a strengthening heat-treatment.

Preliminary experiments have been carried out seeking to examine the effect of plasma activation of a silicon oxide surface layer on the quality of a joined structure obtained by molecular adhesion, as described above in detail. More particularly, these preliminary experiments sought to evaluate the benefit of plasma activation when the plasma incorporates sulfur hexafluoride (SF₆). A summary of the results obtained is shown in the table below.

| | O₂ | SF₆ | | | | Anhydrous | | |
|---|---|---|---|---|---|---|---|---|
| | flow | flow | Duration | F dose by | S dose by | bonding | Duration | |
| | rate | rate | of SF₆ | SIMS | TXRF | energy | of wave | |
| Ref. | (sccm) | (sccm) | (s) | (at/cm²) | (at/cm²) | (mJ/m\hat{ }2) | (s) | Pimples |
| 1 | 75 | 0 | 0 | 3.0E+13 | 2.4E+12 | 1905 | 6 | Yes |
| 2 | 75 | 1 | 7 | — | — | — | — | Yes |
| 3 | 75 | 3 | 3 | — | — | 2859 | 10 | Yes |
| 4 | 75 | 5 | 5 | 5.3E+14 | 3.54E+13 | 2190 | 12 | No |
| 5 | 75 | 3 + 5 | 3 + 5 | — | — | — | 12.5 | No |
| 6 | 75 | 3 | 20 | 4.3E+14 | 7.73E+13 | 2530 | 11.5 | No |
| 7 | 75 | | | 8.9E+14 | 4.74E+12 | 2463 | 7 | Yes |
| 8 | 75 | | | 8.9E+14 | 5.09E+12 | 2599 | 6 | Yes |
| 9 | 75 | | | 6.2E+14 | 4.48E+12 | 2306 | 9.5 | Yes |
| 10 | 75 | | | 8.7E+14 | 3.18E+13 | 2300 | 12 | No |

In these preliminary experiments, the substrates were made up of pairs of 150 mm wafers of lithium tantalate and silicon, each provided with a surface layer of (nitrogen-free) silicon oxide of 30 nm and 650 nm, respectively, deposited by PECVD. The two surface layers each underwent plasma activation for an activation time of 30 seconds at a power of 150 W before being joined according to the process for joining by molecular adhesion presented above. After a strengthening heat-treatment at 180° C. for 60 min, the bonding energy was measured by a double cantilever beam method. The experiments reported in the table were all carried out in a CCP-type plasma apparatus (CCP=capacitively coupled plasma), with the exception of experiment 10, which was carried out in a ICP-type apparatus (ICP=inductively coupled plasma).

### Reference Experiment

Experiment 1 in the table constitutes the reference experiment corresponding to activation of the surface layer with a plasma of oxygen alone. The oxygen flow rate during this activation (and during all experiments reported in this table) was set at 75 SCCM. The bonding energy was measured at 1905 mJ/m^2, the bonding wave was propagated for a period of 6 seconds, and the joined structure exhibited a significant level of pimple-type defects. The analysis of the silicon oxide surface layer by SIMS and TXRF, respectively, revealed incorporation of a fluorine dose of 3.0 E+13 at/cm^2 and of a sulfur dose of 2.4 E+12 at/cm^2, which corresponds to traces of these elements.

### Experiments 2 to 6

In these experiments, a controlled amount of SF6 was introduced during oxygen-based plasma activation, this controlled amount being increasing for experiments 2 to 6. The controlled amount of SF₆ is obtained by adjusting the rate and duration of this flow. This was introduced either at the start of plasma activation or in the middle of this activation, this latter alternative being preferred, since the source plasma is more stable and the phenomena better controlled. It was observed that a significant dose of sulfur and of fluorine had been integrated into the surface layers in the course of the activations carried out during experiments 2 to 6. In experiment 5 the controlled amount of SF₆ was introduced over the course of two sequences, the first resulting in the introduction of 3 SCCM of SF6 for 3 seconds, followed after a pause in this flow by a sequence of 5 SCCM of SF₆ for 5 seconds.

It is recalled that the unit of measurement SCCM (standard cubic centimeters per minute) is a physical unit of the mass flow of a gas, in cm³/min, at a density defined by the standard conditions of temperature and pressure.

### Experiments 7 to 10

In these experiments, the plasma apparatus source activated at 2000 W was supplied with a gas mixture containing about 20% SF6 (10 SCCM) in 80% of oxygen (50 SCCM) in a preliminary step and without either of the substrates of the experiment being placed in this equipment. The purpose of this preliminary step was to prepare the chamber of the plasma activation apparatus with the aim of coating the internal surface of this chamber with sulfur-and fluorine-containing species. The experiments were then performed by treating the silicon oxide surface layers of the substrates with a conventional plasma activation based on oxygen alone in the chamber thus prepared. The sulfur-and/or fluorine-containing species coating the internal surface of the chamber were torn from these surfaces during oxygen plasma activation and integrated in this plasma throughout the duration of the activation.

Compared to reference experiment 1, it was observed that all the other experiments performed resulted in a significant increase in the measured bonding energy. This effect of fluorine, which had already been reported elsewhere, appears to be brought about by the incorporation of fluorine into the surface layer at a dose of greater than 4.0 E14 at/cm^2.

More surprisingly, these results show that the velocity of the bonding wave is influenced by the dose of sulfur incorporated into the dielectric surface layer: the greater this dose, the more this velocity is reduced. This effect is obtained without significantly influencing the bonding energy and in all cases the bonding energy remains greater than the bonding energy in the reference experiment. It therefore appears possible to control the velocity of this wave by regulating the dose of sulfur introduced into the dielectric surface layer.

If this dose of sulfur is sufficient—greater than 3.0 E13 at/cm^2 and preferably greater than 3.5 E13 at/cm^2—this wave velocity is sufficiently low that pimple-type defects are no longer present to a significant degree, as was revealed by experiments 4, 5, 6 and 10.

Other experiments were able to reproduce these results for dielectric surface layers other than the silicon oxide (SiO₂) layers that were the subject of the experiments reported in the table. In particular, similar results were obtained when the dielectric surface layer was formed of silicon oxide having a nitrogen/oxygen ratio of strictly greater than 0, and when this dielectric surface layer was formed of silicon nitride.

These experiments and these observations have been exploited to propose a process for joining by molecular adhesion with which it is possible to prevent or at least limit the occurrence of pimple-type bonding defects. Moreover, this benefit can be obtained without affecting the bonding energy of the joined structure, and even providing a significantly improved bonding energy.

In the sequence made up of the steps presented above of contacting of the main faces of the two substrates and initiating and propagating of a bonding wave between the two substrates, a process according to the present disclosure therefore provides, before the contacting step, a step of preparing of the dielectric surface layer with the aim of introducing into this layer a dose of sulfur of greater than 3.0 E13 at/cm^2. It is advantageous when this dose is greater than 3.5 E13 at/cm^2. This dose can be measured by TXRF measurement or by SIMS measurement, as was the case in the reported experiments.

It is advantageous when this dose corresponds to the dose present in a thickness of not more than 10 nm, or even 7.5 nm, immediately below the main face of the substrate, since it is probable that the bonding characteristics can be influenced only up to this thickness.

To also benefit from an improved bonding energy while limiting the occurrence of pimple-type defects, it is also possible to seek to introduce into the dielectric surface layer a fluorine dose of 4.0 E14 at/cm^2. Here too, it is advantageous when this dose corresponds to the dose present in a thickness of not more than 10 nm, or even 7.5 nm, immediately below the main face of the substrate, since it is probable that the bonding characteristics can be influenced only up to this thickness. This dose can be measured by TXRF measurement or by SIMS measurement.

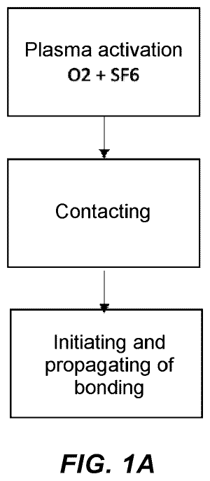

A first approach permitting the introduction of sulfur at a target dose can consist of plasma activation of the dielectric surface layer by way of a gas comprising sulfur, such as sulfur hexafluoride. This approach is the subject of FIG. 1A.

The gas comprising sulfur, for example, sulfur hexafluoride, may be mixed with an activating gas constituted, for example, of oxygen or nitrogen. This mixture is dosed such that the target dose of sulfur (and optionally of fluorine) is attained or exceeded by the end of the plasma activation step.

The duration of such a plasma activation is typically between 15 seconds and two minutes. More precisely, the duration of activation is the period of time from the moment of plasma ignition in the apparatus source to the extinction thereof. During this time, the dielectric surface layer is exposed to a plasma formed from an activating gas of oxygen or nitrogen.

The gas comprising sulfur may be introduced at a controlled flow rate throughout this time, or just for part of this time, so as to mix it with the oxygen or nitrogen for a specified period of the activation time. This specified period preferably does not include the moment of plasma ignition, since this ignition can result in sulfur-and fluorine-containing species present in the plasma being introduced into the surface layer in a non-repeatable manner, which makes it impossible to achieve perfect control of the doses introduced and can be detrimental to good process control, especially when the target doses of sulfur, and of fluorine when employed, are close to the limit doses. It is therefore advantageous when the specified period during which the dielectric surface layer is exposed to a plasma formed from a gas comprising sulfur is respectively preceded and followed by periods during which the dielectric surface layer is exposed to a plasma formed from an activating gas of oxygen or nitrogen.

Completing the description of FIG. 1A, the step of preparing the dielectric surface layer with the aim of introducing into this layer a dose of sulfur of greater than 3.0 E13 at/cm^2 is followed by the step of contacting of the main faces of the two substrates, then by the step of initiating and propagating of a bonding wave between the main faces of the two substrates so as to join the two faces together.

As mentioned in a previous section, a step of cleaning of the main face of the substrate may be provided between the preparation step and the contacting step. This cleaning step may correspond to or include the brushing of this face while pouring on a liquid such as demineralized water. It is advantageous when the cleaning step is applied to the main faces of both substrates, immediately before they are joined.

According to another approach, depicted in FIG. 1B, the preparation step includes preparing the chamber of the plasma activation apparatus by way of a plasma of a gas comprising sulfur and then, once the chamber has been prepared, treating the dielectric surface layer of at least one of the substrates, in the chamber, with a plasma comprising oxygen or nitrogen.

As has already been shown, the plasma activation by way of a plasma of a gas comprising sulfur is performed while the substrate to be prepared is not present in the chamber. The gas comprising sulfur may be sulfur hexafluoride mixed with an activating gas such as oxygen or nitrogen. The purpose of this sub-step is to coat the internal surface of the chamber with sulfur-containing species, and optionally fluorine-containing species, these species then being torn from the internal surface during plasma activation of the dielectric surface layer provided in the sub-step following the preparation step. The parameters (especially the flow rate of the sulfur-containing gas, the duration of the plasma and the power thereof) are adjusted such that sufficient species are generated and incorporated into the surface layer during the sub-step following the plasma activation.

Completing the description of FIG. 1B, the step of preparing the dielectric surface layer according to this approach is also followed by the step of contacting of the main faces of the two substrates, then by the step of initiating and propagating of a bonding wave between the main faces of the two substrates so as to join the two faces together. The cleaning step described in the description of the previous approach may also be provided.

The dielectric surface layer is advantageously a layer of silicon oxide, into which nitrogen may be incorporated in any desired proportion, or a layer of silicon nitride.

Before, during or at the end of the steps of the joining process as described above, it is, of course, possible to apply further steps to the substrates, especially those of a process for producing a structure obtained by joining two substrates by molecular adhesion.

In some embodiments, a strengthening heat-treatment may be applied to the joined structure and steps may be carried out to reduce the thickness of at least one of the two substrates so as to form a layer. This reduction in thickness can be achieved by thinning of the substrate (for example by grinding) or by fracturing. In this case, lightweight species may be introduced into the substrate to be fractured (typically before the contacting step of the joining process) with the aim of forming a fragile fracture plane in the substrate where a reduction in thickness is desired.

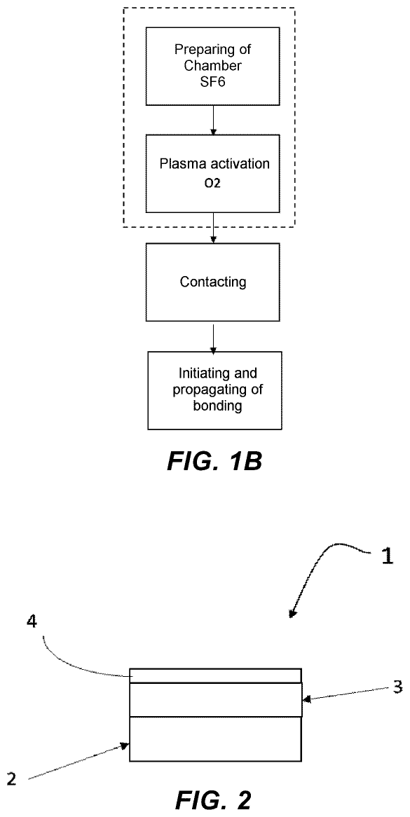

In the present disclosure where the joining process is part of a process for the transfer of a layer, what is present on conclusion of this process (cf. FIG. 2) is a structure 1 comprising a support substrate 2, a dielectric buried layer 3, which is advantageously a layer of silicon oxide or of silicon nitride, on and in contact with the support substrate 2, and a layer termed a “working layer” 4 on and in contact with the dielectric buried layer 3.

The buried layer has a bonding interface corresponding to its interface with the support substrate 2, to its interface with the working layer 4 or incorporated into its thickness, depending on whether the process has implemented a single dielectric surface layer arranged on one or the other of the substrates or two such layers arranged on each of the main faces of the substrates.

This dielectric buried layer 3 contains a dose of sulfur of greater than 3.0 E13 at/cm^2 and advantageously greater than 3.5 E13 at/cm^2. It may have a dose of fluorine of greater than 4.0 E14 at/cm^2. As stated previously, when the dielectric buried layer is composed of silicon oxide, it may incorporate other species, especially nitrogen. It is advantageous when these doses correspond to those present in a thickness of not more than 10 nm on one and/or the other side of the bonding interface.

The present disclosure is, of course, not limited to the embodiments described, and implementation variants may be applied thereto without departing from the scope of the present disclosure as defined by the claims.

Although sulfur hexafluoride was taken here as an example of a gas comprising sulfur (and fluorine), the present disclosure is in no way limited to the use of this gas. It is especially possible to envisage using instead any sulfur-containing gas such as sulfuryl fluoride (SO₂F₂) or thionyl tetrafluoride (SO₂F₄).

The preparation step according to the present disclosure may be applied to a single dielectric surface layer formed on one of the substrates even when both substrates comprise such a dielectric surface layer. The preparation step may likewise be applied to each of the substrates when each is provided with a dielectric surface layer.

Finally, in an alternative not described in detail, the sulfur-containing species, and fluorine-containing species if present, may be incorporated into the dielectric surface layer during their formation, for example during the oxidation or nitridation of a silicon-containing substrate, or during the deposition thereof.

In the claims:

1. A method of joining, by molecular adhesion, two substrates each having a main face, at least one of the two substrates including a dielectric surface layer on the side of its main face, the method comprising:
introducing sulfur into the dielectric surface layer at a dose greater than 3.0 E13 at/cm^2; then
contacting the main faces of the two substrates; then
initiating and propagating a bonding wave between the main faces of the two substrates to join the main faces together and form a joined structure.

2. The method of claim 1, wherein introducing the sulfur into the dielectric surface layer at the dose greater than 3.0 E13 at/cm^2 comprises introducing the sulfur into the dielectric surface layer at a dose greater than 3.5 E13 at/cm^2.

3. The method of claim 1, further comprising introducing fluorine into the dielectric surface layer at a dose of greater than 4.0 E14 at/cm^2.

4. The method of claim 1, further comprising activating the dielectric surface layer by a plasma of a gas comprising sulfur.

5. The method of claim 4, wherein the plasma also comprises oxygen or nitrogen.

6. The method of claim 5, wherein the activating of the dielectric surface layer is carried out for an activation time of between 15 seconds and 2 minutes.

7. The method of claim 6, wherein the dielectric surface layer is exposed to a plasma of oxygen or nitrogen throughout the duration of the activation, and a controlled amount of sulfur hexafluoride is mixed with the oxygen or nitrogen for a specified period of the activation time.

8. The method of claim 7, wherein the specified period is respectively preceded and followed by periods during which the dielectric surface layer is exposed to a plasma formed from an activating gas of oxygen or nitrogen.

9. The method of claim 1, further comprising, prior to the contacting, preparing a chamber of a plasma activation apparatus with a plasma of a gas comprising sulfur and then, once the chamber has been prepared, treating the dielectric surface layer in the chamber with a plasma comprising oxygen or nitrogen.

10. The method of claim 1, further comprising applying a heat-treatment to the joined structure.

11. The method of claim 1, wherein the two substrates are provided with a dielectric surface layer of silicon oxide or silicon nitride on the side of their main face, and the method further comprises introducing sulfur into each of the dielectric surface layers at a dose greater than 3.0 E13 at/cm^2.

12. The method of claim 1, wherein the dielectric surface layer is silicon oxide.

13. The method of claim 1, further comprising cleaning of at least one of the main faces of the two substrates after the introducing the sulfur into the dielectric surface layer and before the contacting.

14. A structure comprising a support substrate, a dielectric buried layer on and in contact with the support substrate, and a working layer on and in contact with the buried layer, wherein the dielectric buried layer contains a dose of sulfur of greater than 3.0 E13 at/cm^2.

15. The structure of claim 14, wherein the dose of sulfur is greater than 3.5 E13 at/cm^2.

16. The structure of claim 15, wherein the dielectric buried layer contains a dose of fluorine of greater than 4.0 E14 at/cm^2.

17. The structure of claim 14, wherein the dielectric buried layer is silicon oxide.

18. The method of claim 4, wherein the gas comprising sulfur is sulfur hexafluoride.

19. The method of claim 2, further comprising introducing fluorine into the dielectric surface layer at a dose of greater than 4.0 E14 at/cm^2.

20. The method of claim 2, further comprising activating the dielectric surface layer by a plasma of a gas comprising sulfur.
